(19) United States
(12) Patent Application Publication
(10) Pub. No.: US 2008/0239021 A1
(43) Pub. Date: Oct. 2, 2008

(54) Liquid Ejection Head And Method Of Manufacturing The Same

(75) Inventor: Hidetoshi Watanabe, Tokoname-shi (JP)

Correspondence Address: BAKER BOTTS LLP;C/O INTELLECTUAL PROPERTY DEPARTMENT, THE WARNER, SUITE 1300, 1299 PENNSYLVANIA AVE, NW, WASHINGTON, DC, 20004-2400, US

(73) Assignee: BROTHER KOGYO KABUSHIKI KAISHA, Nagoya-shi (JP)

(21) Appl. No.: 12/057,933

(22) Filed: Mar. 28, 2008

(30) Foreign Application Priority Data
Mar. 29, 2007 (JP) 2007-086712

(51) Int. Cl. B41J 2/045; H01L 41/18

(52) U.S. Cl. 347/70; 347/71; 29/25.35

(57) ABSTRACT

A liquid ejection head includes a passage member in which individual liquid passages are formed, diaphragms fixed to a plane of the passage member, piezoelectric layers formed on the diaphragms, individual electrodes formed on the respective piezoelectric layers, lands electrically connected to the respective individual electrodes. The lands have their height from a surface of the piezoelectric layers higher than that of the individual electrodes. Each of the individual liquid passages has a liquid ejection opening and a pressure chamber an interior space of which exposes on the plane. An overhang is formed on a side wall of each pressure chamber in such a manner that a length of an interior space of the pressure chamber along the plane increases at a portion more distant from the plane. At least a part of the land overlaps the overhang when seen in a direction perpendicular to the plane.

### CROSS REFERENCE TO RELATED APPLICATION

The present application claims priority from Japanese Patent Application No. 2007-086712 which was filed on Mar. 29, 2007, the disclosure of which is herein incorporated by reference in its entirety.

### BACKGROUND OF THE INVENTION

1. Field of the Invention

The present invention relates to a liquid ejection head which ejects liquid from a liquid ejection opening, and to a method of manufacturing the liquid ejection head.

2. Description of Related Art

In order that an ink-jet type recording apparatus which performs printing by ejecting ink droplets realizes high-resolution printing, it is necessary to increase the number of nozzles formed in a head and in addition arrange the nozzles at a high density. In a head using piezoelectric elements, pressure chambers are formed so as to correspond to the respective nozzles. The number of pressure chambers increases as the number of nozzles increases. A possible way of arranging the pressure chambers at a high density is to reduce a plane area of the pressure chambers. However, merely reducing the plane area of the pressure chambers leads to deterioration in drive efficiency. Therefore, for example, Japanese Unexamined Patent Publication No. 2002-248765 proposes devising a planar shape of a pressure chamber to thereby prevent deterioration in drive efficiency while realizing a high-density arrangement of pressure chambers.

### SUMMARY OF THE INVENTION

However, in a head disclosed in the above-mentioned publication, as clearly seen from FIGS. 1 and 2, an electrical pad which is electrically connected to a drive signal source is disposed so as to be opposed to a side wall of a pressure chamber, that is, disposed outside a region opposed to a pressure chamber. Therefore, it is necessary to ensure a region for the electrical pad in addition to a region for the pressure chamber in a plan view. This makes it difficult for the pressure chambers to be arranged at a high density.

An object of the present invention is to provide a liquid ejection head which efficiently allows pressure chambers to be arranged at a high density, and also to provide a method of manufacturing the liquid ejection head.

According to a first aspect of the present invention, there is provided a liquid ejection head comprising a passage member, one or a plurality of diaphragms, a plurality of piezoelectric layers, a plurality of individual electrodes, and a plurality of lands. The passage member includes a plurality of individual liquid passages each of which has a liquid ejection opening and a pressure chamber corresponding to the liquid ejection opening, and a plane on which a plurality of openings are formed to expose an interior space of each pressure chamber. The one or a plurality of diaphragms are fixed to the plane so as to close the openings. The plurality of piezoelectric layers are spaced apart from each other with respect to a direction along the plane and formed on the diaphragms so as to be opposed to the respective pressure chambers. The plurality of individual electrodes are formed on the respective piezoelectric layers. The plurality of lands are electrically connected to the respective individual electrodes and have their height from a surface of the piezoelectric layers higher than that of the individual electrodes. An overhang is formed on a side wall of each pressure chamber in such a manner that a length of the interior space along the plane increases at a portion more distant from the plane. At least a part of each land overlaps the overhang of a pressure chamber corresponding to the land when seen in a direction perpendicular to the plane.

In the first aspect, the land is positioned above the overhang. This enables the pressure chambers to be arranged at a higher density as compared with when the land is positioned out of a region opposed to the pressure chamber.

According to a second aspect of the present invention, there is provided a method of manufacturing a liquid ejection head, comprising the steps of: preparing a passage member including a plurality of individual liquid passages each of which has a liquid ejection opening and a pressure chamber corresponding to the liquid ejection opening, and a plane on which a plurality of openings are formed to expose an interior space of each pressure chamber; fixing one or a plurality of diaphragms to the plane so as to close the openings; placing a piezoelectric layer on the diaphragms so as to be opposed to the pressure chambers; placing a plurality of individual electrodes on the piezoelectric layer so as to be opposed to the respective pressure chambers; forming a plurality of lands which are electrically connected to the respective individual electrodes and which have their height from a surface of the piezoelectric layer higher than that of the individual electrodes; and dividing the piezoelectric layer into a plurality of sections which are opposed to the respective pressure chambers and spaced apart from each other with respect to a direction along the plane. In the step of preparing the passage member, an overhang is formed on a side wall of each pressure chamber in such a manner that a length of the interior space along the plane increases at a portion more distant from the plane, and in addition each of the openings is positioned within each of a plurality of quadrangle regions by which the plane is sectioned into a grid. In the step of forming the lands, a whole of each land is made accommodated within the quadrangle region, and at least a part of each land is made overlap the overhang of a pressure chamber corresponding to the land when seen in a direction perpendicular to the plane.

In the second aspect, the whole of the land is accommodated within the quadrangle region. Therefore, in the step of dividing, the piezoelectric layer may be divided straight. Accordingly, the piezoelectric layer can be easily divided by the cutter.

### BRIEF DESCRIPTION OF THE DRAWINGS

Other and further objects, features and advantages of the invention will appear more fully from the following description taken in connection with the accompanying drawings in which:

FIG. 1 is a schematic side view showing a general structure of an ink-jet printer which includes an ink-jet head according to an embodiment of the present invention;

FIG. 2 is a sectional view of the ink-jet head shown in FIG. 1, as taken along a width thereof;

FIG. 3 is a plan view of a head main body shown in FIG. 2;

FIG. 4 is an enlarged view of a region which is enclosed by an alternate long and short dash line in FIG. 3;

FIG. 5 is a sectional view as taken along line V-V in FIG. 4;

FIG. 6 is an enlarged view of a region which is enclosed by an alternate long and short dash line in FIG. 5;

FIG. 7 is a plan view of an actuator shown in FIG. 6;

FIG. 8 is an explanatory view showing a part of actuators and pressure chambers arranged within one actuator group;

FIG. 9 is a flowchart showing a method of manufacturing the head main body;

FIG. 10 is a view corresponding to FIG. 6 and showing a first modification of an overhang;

FIG. 11 is a view corresponding to FIG. 6 and showing a second modification of an overhang;

FIG. 12 is a view corresponding to FIG. 6 and showing a third modification of an overhang;

FIG. 13 is a view corresponding to FIG. 7 and showing a first modification of a land position;

FIG. 14 is a view corresponding to FIG. 7 and showing a second modification of a land position;

FIG. 15A is a plan view showing a modification of an individual electrode; and

FIG. 15B is a sectional view as taken along line B-B in FIG. 15A.

### DESCRIPTION OF THE PREFERRED EMBODIMENTS

In the following, a certain preferred embodiment of the present invention will be described with reference to the accompanying drawings.

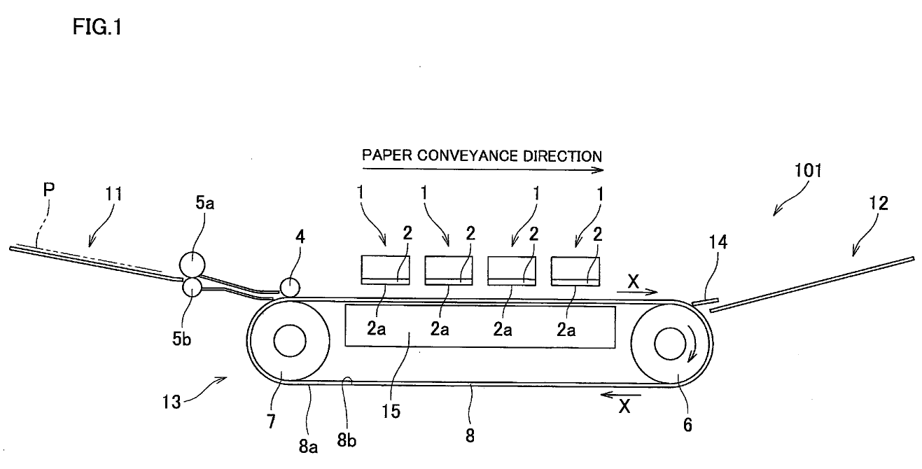

As shown in FIG. 1, an ink-jet printer 101 according to an embodiment of the present invention is a color ink-jet printer including four ink-jet heads 1. The ink-jet printer 101 has a paper feed tray 11 and a paper discharge tray 12 in left and right parts in FIG. 1, respectively. In the ink-jet printer 101, a paper conveyance path through which a paper P is conveyed from the paper feed tray 11 to the paper discharge tray 12. A pair of feed rollers 5a and 5b, which feed out the paper P from the paper feed tray 11 to a right side in FIG. 1 while pinching the paper P, are provided immediately downstream of the paper feed tray 11.

A belt conveyor mechanism 13 is provided in a middle of the paper conveyance path. The belt conveyor mechanism 13 includes two belt rollers 6 and 7, an endless conveyor belt 8 which is wound between the rollers 6 and 7, and a platen 15 which is placed in a region enclosed by the conveyor belt 8 and at a position opposed to the ink-jet heads 1. The platen 15 supports the conveyor belt 8 to prevent the conveyor belt 8 from bending downward in an image forming region which is opposed to the ink-jet heads 1. A pressing roller 4 is disposed at a position opposed to the belt roller 7. The pressing roller 4 presses the paper P, which has been fed out from the paper feed tray 11 by the feed rollers 5a and 5b, onto an outer surface 8a of the conveyor belt 8.

As the belt roller 6 is rotated clockwise in FIG. 1 by a conveyor motor (not shown), the conveyor belt 8 travels along an arrow X. As a result, the paper P pressed onto the outer surface 8a of the conveyor belt 8 by the pressing roller 4 is conveyed toward the paper discharge tray 12 while being kept on the outer surface 8a.

A peeling plate 14 is provided immediately downstream of the belt roller 6 with respect to the paper conveyance path. The peeling plate 14 peels the paper P, which is kept on the outer surface 8a of the conveyor belt 8, off the outer surface 8a and sends the paper P toward the paper discharge tray 12.

The four ink-jet heads 1 are arranged in parallel with respect to a paper conveyance direction, and eject magenta ink, yellow ink, cyan ink, and black ink, respectively. Thus, the ink-jet printer 101 is a line-type printer. Each of the ink-jet heads 1 has a head main body 2 at its lower end. The head main body 2 has a rectangular parallelepiped shape elongated in a direction perpendicular to the paper conveyance direction. A lower face of the head main body 2 serves as an ink ejection face 2a which is opposed to the outer surface 8a. While the paper P conveyed by the conveyor belt 8 is passing just under the four head main bodies 2a in order, ink of respective colors is ejected from the ink ejection faces 2a of the head main bodies 2 toward a surface of the paper P, so that a desired color image is formed on the surface of the paper P.

Next, the ink-jet head 1 will be described.

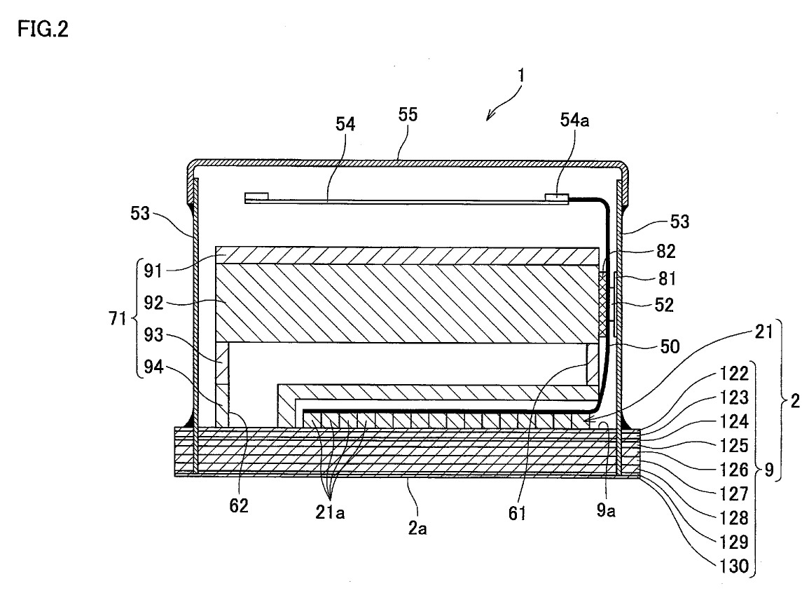

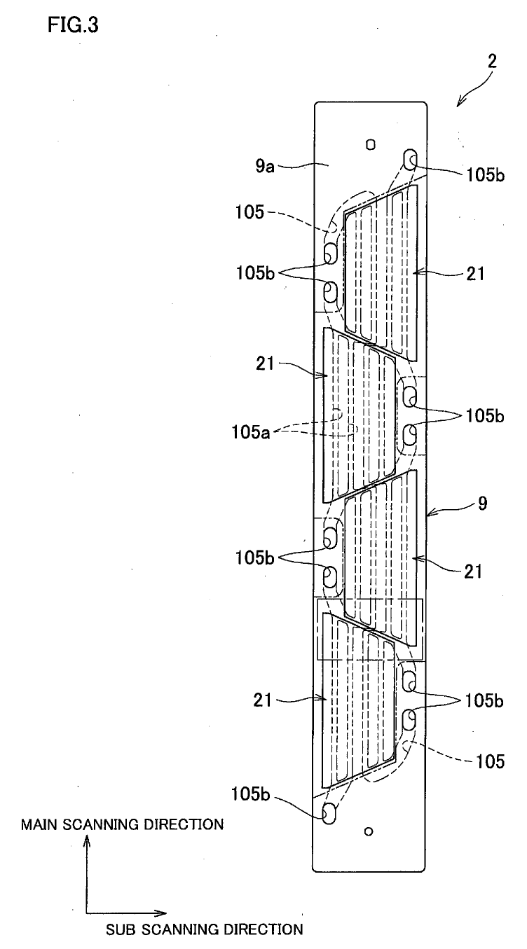

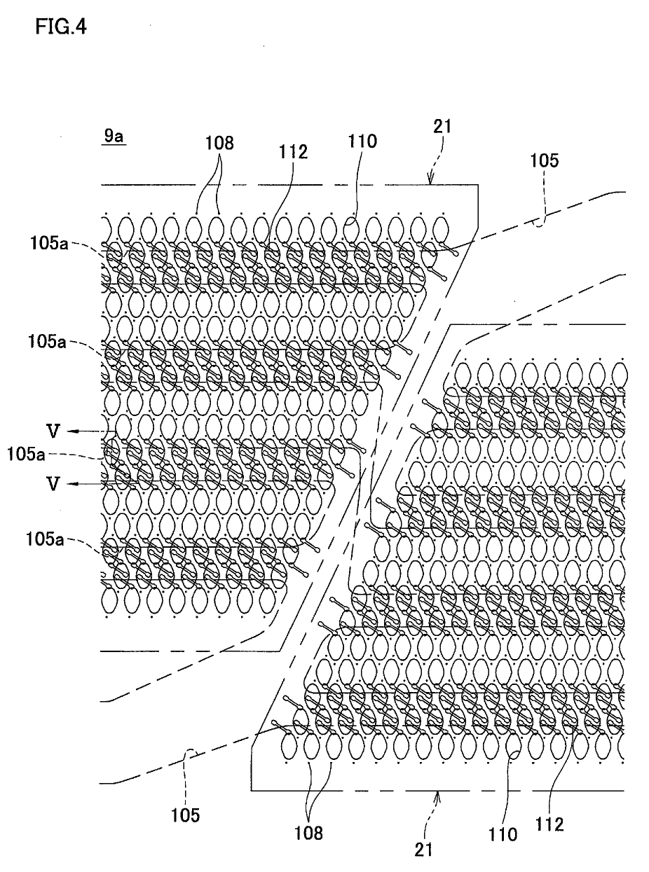

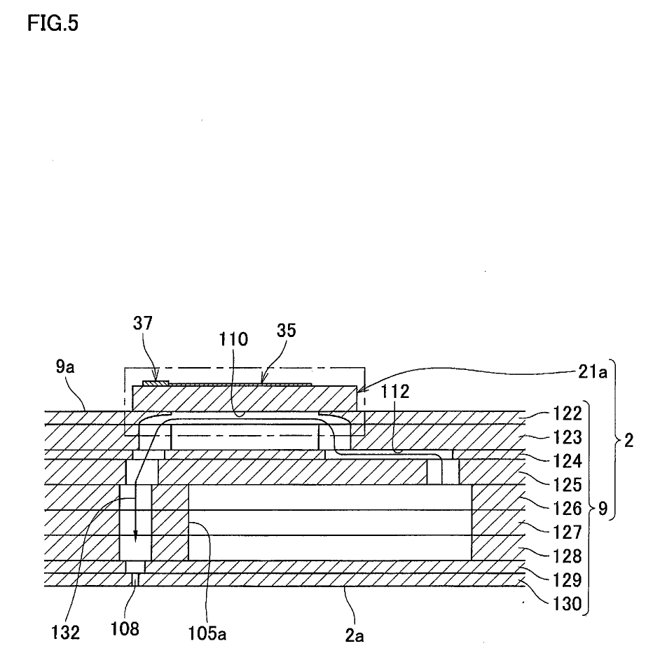

As shown in FIG. 2, the head main body 2 provided at the lower end of the ink-jet head 1 includes a passage unit 9 and four actuator groups 21 (regions of which are illustrated with solid lines in FIG. 3 and alternate long and two short dashes lines in FIG. 4). As shown in FIGS. 3 and 4, in a region of an upper face 9a of the passage unit 9 corresponding to each actuator group 21, a plurality of pressure chambers 110 are formed in a matrix. On a lower face of the passage unit 9, that is, the ink ejection face 2a, a region corresponding to each actuator group 21 serves as an ink ejection region where a plurality of nozzles 108 are arranged in a matrix. A distal end of each nozzle 108 forms an ink ejection opening. The plurality of nozzles 108 are disposed so as to correspond to the respective pressure chambers 110. The actuator group 21 includes a plurality of actuators 21a which are provided individually for the respective pressure chambers 110. The actuator 21a selectively applies ejection energy to ink contained in the pressure chamber 110. The actuators 21a are fixed to the upper face of the passage unit 9 in such a manner that each actuator 21a closes an opening of the corresponding pressure chamber 110 (see FIG. 5).

Referring to FIG. 2 again, one end of a COF (Chip On Film) 50 is fixed over upper faces of all actuators 21a included in each actuator group 21. Each terminal (not shown) of the COF 50 is electrically connected to each actuator 21a. The COF 50 is a flat-type flexible circuit board mounted with a driver IC 52. The other end of the COF 50 is electrically connected to a control board 54. The control board 54 controls driving of the actuator 21a via the driver IC 52. The driver IC 52 generates a drive signal for driving the actuator 21a.

A reservoir unit 71 which supplies ink to the passage unit 9 is fixed to an upper face of the head main body 2. The actuator group 21, the reservoir unit 71, the COF 50, and the control board 54 are covered by side covers 53 and a head cover 55. The side covers 53 which are metal plates extend in a lengthwise direction of the passage unit 9. The side covers 53 are fixed to the upper face of the passage unit 9, near both widthwise ends thereof. The head cover 55 is fixed to upper ends of the two side covers 53 so as to extend over the two side covers 53.

The reservoir unit 71 includes four plates 91, 92, 93, and 94 laminated to each other. Within the reservoir unit 71, an ink inflow passage (not shown), an ink reservoir 61, and ten ink outflow passages 62 (only one of which is shown in FIG. 2) are formed so as to communicate with each other. Ink flows from an ink supply source such as an ink tank (not shown) into the ink inflow passage. The ink reservoir 61 temporarily reserves ink therein. The ink outflow passages 62 communicate with the passage unit 9 via ten ink supply openings 105b which are formed on the upper face of the passage unit 9 (see FIG. 3). Ink supplied from the ink supply source passes sequentially through the ink inflow passage, the ink reservoir 61, and the ink outflow passages 62, and then the ink is supplied through the ink supply openings 105b to the passage unit 9. A lower face of the plate 94 is made uneven so that a gap appears between the plate 94 and the COF 50.

The COF 50 extends upward between the side cover 53 and the reservoir unit 71, and the other end thereof is connected to a connector 54a which is mounted to the control board 54. The driver IC 52 is biased toward the side cover 53 by a sponge 82 which is attached to a side face of the reservoir unit 71, and fixed to the side cover 53 with interposition of a heat sink 81.

Next, the head main body 2 will be described in more detail with reference to FIGS. 3, 4, 5, 6, 7, and 8. As described above, the head main body 2 includes the passage unit 9 and the four actuator groups 21 (see FIG. 3). Here, in FIGS. 3 and 4, the actuators 21a included in the actuator groups 21 are not shown, and only regions of the actuator groups 21 are shown. In FIG. 4, apertures 112 and nozzles 108 are illustrated with solid lines, although they should actually be illustrated with broken lines because they are formed within the passage unit 9 and on the lower face of the passage unit 9, respectively.

The passage unit 9 has a rectangular parallelepiped shape, and its plan view is substantially the same as that of the plate 94 of the reservoir unit 71. As shown in FIG. 3, a total of ten ink supply openings 105b, which correspond to the ink outflow passages 62 of the reservoir unit 71 (see FIG. 2), are provided on the upper face 9a of the passage unit 9. Formed within the passage unit 9 are manifold channels 105 which communicate with the ink supply openings 105b, and sub manifold channels 105a which branch from the sub manifold channels 105.

In this embodiment, as shown in FIG. 4, a plurality of pressure chambers arranged at regular intervals form rows of pressure chambers 110 extending in the lengthwise direction of the passage unit 9, and there are sixteen rows of pressure chambers 110 in one actuator group 21. The number of pressure chambers 110 included in a pressure chamber row increases as the pressure chamber row locates closer to a longer side (lower base) of a trapezoidal region of the actuator group 21, while it decreases as the pressure chamber row locates closer to a shorter side (upper base) of the trapezoidal region of the actuator group 21. The same applies to nozzles 108.

In a plan view, each pressure chamber 110 has a rhombic shape with rounded corners. A longer diagonal of the rhombic shape is in parallel with a widthwise direction of the passage unit 9. One end of each pressure chamber 110 corresponding to one acute portion of the pressure chamber 110 communicates with a nozzle 108, and the other end thereof corresponding to the other acute portion communicates with a sub manifold channel 105a through an aperture 112.

As shown in FIG. 5, the passage unit 9 includes nine plates made of a metal such as stainless steel, namely, a cavity plate 122, a base plate 123, an aperture plate 124, a supply plate 125, three manifold plates 126, 127, 128, a cover plate 129, and a nozzle plate 130, in this order from the top. In a plan view, each of the plates 122 to 130 has a rectangular shape elongated in a main scanning direction.

The cavity plate 122 is a metal plate in which formed are a plurality of, substantially parallelogram openings serving as pressure chambers 110. The base plate 123 is a metal plate in which formed are communication holes each connecting each pressure chamber 110 of the cavity plate 122 to an aperture 112, and communication holes each connecting each pressure chamber 110 to a nozzle 108. The aperture plate 124 is a metal plate in which formed are apertures 112 each corresponding to each pressure chamber 110 of the cavity plate 122. In addition, communication holes each connecting each pressure chamber 110 to a nozzle 108 are also formed in the aperture plate 124. The supply plate 125 is a metal plate in which formed are communication holes each corresponding to each pressure chamber 110 of the cavity plate 122 and each connecting an aperture 112 to a sub manifold channel 105a, and also communication holes each connecting each pressure chamber 110 to a nozzle 108. The manifold plates 126, 127, and 128 are metal plates in which formed are, in addition to sub manifold channels 105a, communication holes each connecting each pressure chamber 110 of the cavity plate 122 to a nozzle 108. The cover plate 129 is a metal plate in which formed are communication holes each connecting each pressure chamber 110 of the cavity plate 122 to a nozzle 108. The nozzle plate 130 is a metal plate in which formed are holes each corresponding to each pressure chamber 110 of the cavity plate 122 and serving as nozzles 108.

The plates 122 to 130 are positioned in layers in such a manner that manifold channels 105, sub manifold channels 105a, and a plurality of individual ink passages 132 are formed within the passage unit 9. Each of the individual ink passages 132 extends from an outlet of a sub manifold channels 105a to a nozzle 108 through an aperture 112 which functions as a throttle and a pressure chamber 110 (see FIG. 5). The individual ink passages 132 are provided individually for the respective pressure chambers 110. The individual ink passage 132 extends upward from the sub manifold channel 105a, then spreads horizontally in the aperture 112, then extends further upward, and thus communicates with the pressure chamber 110. In the pressure chamber 110, the individual ink passage 132 spreads horizontally again, then extends obliquely downward and slightly away from the aperture 112, and then extends vertically downward to a nozzle 108.

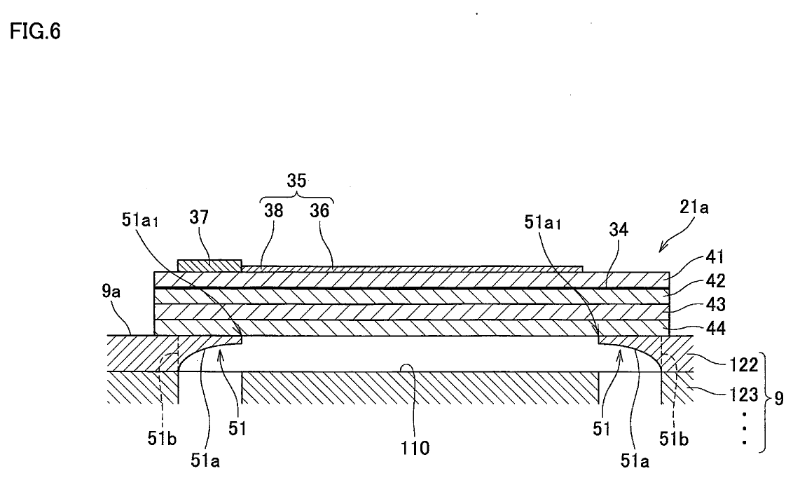

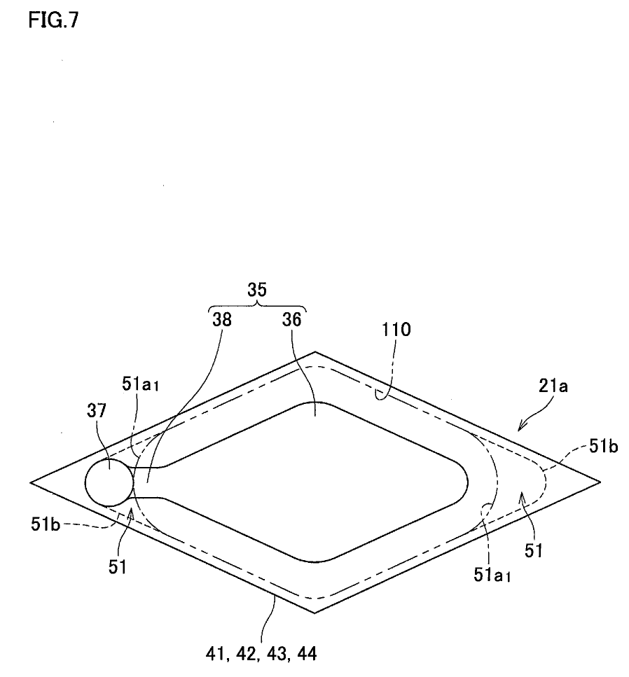

As shown in FIG. 6, overhangs 51 each having a curved shape in a sectional view are formed in the cavity plate 122. The overhang 51 is provided at a portion corresponding to a vicinity of each acute portion of the pressure chamber 110 which has a rhombic shape in a plan view. Due to the overhangs 51, an interior space of the pressure chamber 110 has such a shape that its length along the upper face 9a of the passage unit 9 (i.e., a length along a horizontal direction in FIG. 6) is minimum within a region between the upper face 9a and a slightly lower portion while the length increases at a further lower portion more distant from the upper face 9a. In the cavity plate 122, the overhang 51 means a portion of the cavity plate 122 sandwiched between an annular curved surface 51b and a side face 51a of the pressure chamber 110. The annular curved surface 51b is defined by extending, in a thickness direction of the cavity plate 122, an intersection line between the base plate 123 and the side face 51a of the pressure chamber 110. As shown in FIG. 7, in a plan view, the overhang 51 is defined as a region enclosed by an outer edge of the annular curved surface 51b and an inner edge 51a1 which is an intersection line between the side face 51a and the upper face 9a.

Next, the actuator group 21 will be described.

As shown in FIG. 3, the four actuator groups 21 each having a trapezoidal region are arranged in a zigzag pattern in the main scanning direction so as to keep away from the ink supply openings 105b. Parallel opposed sides of the trapezoidal region of the actuator group 21 extend in the lengthwise direction of the passage unit 9. Oblique sides of trapezoidal regions of every neighboring actuator groups 21 overlap each other with respect to a sub scanning direction.

As shown in FIG. 6, each actuator 21a of the actuator group 21 has four piezoelectric sheets 41, 42, 43, and 44, an individual electrode 35, a common electrode 34 having a thickness of approximately 2 μm, and a land 37 having a circular shape. The individual electrode 35 is formed on an upper face of the uppermost piezoelectric sheet 41. The common electrode 34 is formed between the piezoelectric sheet 41 and the piezoelectric sheet 42 disposed under the piezoelectric sheet 41 so as to extend over an entire surface of the piezoelectric sheets 41 and 42. The land 37 is electrically connected to the individual electrode 35. There is no electrode between the piezoelectric sheets 42 and 43, and between the piezoelectric sheets 43 and 44.

The piezoelectric sheets 41 to 44 are made of a lead zirconate titanate (PZT)-base ceramic material having ferroelectricity. Each of the piezoelectric sheets 41 to 44 has a thickness of approximately 15 μm, and has a parallelogram shape corresponding to a region of one pressure chamber 110 as shown in FIG. 7. In a plan view, a whole of a pressure chamber 110 falls within corresponding piezoelectric sheets 41 to 44.

Both of the individual electrodes 35 and the common electrode 34 are made of, e.g., an Ag—Pd-base metal material. As shown in FIG. 7, the individual electrode 35 includes a main electrode portion 36 and an extension 38. In a plan view, the main electrode portion 36 has a substantially parallelogram shape which is similar to but slightly smaller than the pressure chamber 110. The extension 38 is a portion extending from one acute portion of the main electrode portion 36 in a lengthwise direction of the main electrode portion 36. The main electrode portion 36 is placed within a region opposed to the corresponding pressure chamber 110. The extension 38 extends out from one end of the main electrode portion 36 to a region not opposed to the pressure chamber 110. The main electrode portion 36 and the extension 38 have a thickness of approximately 1 μm.

The land 37 is made of gold including glass frits for example, and has a diameter of approximately 160 μm. The land 37 is bonded onto a surface of a distal end of the extension 38. Therefore, a height of the land 37 from a surface of the piezoelectric sheet 41 is higher than a height of the main electrode portion 36 and the extension 38 from the surface of the piezoelectric sheet 41 (see FIG. 6). A terminal (not shown) of the COF 50 is pressure-bonded to each land 37. In a plan view, a whole of the land 37 overlaps the overhang 51.

Each of the common electrode 34 and the individual electrode 35 is connected to the driver IC 52 through a wire which is provided on the COF 50 (see FIG. 2). A signal which is held at the ground potential is supplied from the driver IC 52 to the common electrode 34. A drive signal which alternately takes the ground potential and a positive potential in accordance with an image pattern to be printed is supplied from the driver IC 52 to the individual electrode 35.

Here, a driving mode of the actuator 21a will be described. The piezoelectric sheet 41 is polarized in its thickness direction. That is, the actuator 21a has a so-called unimorph structure in which the piezoelectric sheet 41 which is most distant from the pressure chamber 110 is a layer including an active portion and the lower three piezoelectric sheets 42 to 44 which are near the pressure chamber 110 are inactive layers. When the individual electrode 35 is set at a predetermined positive or negative potential so that an electric field in the thickness direction is applied to the active portion of the piezoelectric sheet 41 which is sandwiched between the individual electrode 35 and the common electrode 34, the active portion contracts in a direction perpendicular to the thickness direction, that is, in its plane direction, because of a transversal piezoelectric effect. On the other hand, since the piezoelectric sheets 42 to 44 are not affected by the electric field, they do not deform by themselves. Thus, a difference occurs between distortion in the plane direction of the upper piezoelectric sheet 41 and distortion in the plane direction of the lower piezoelectric sheets 42 to 44. As a result, the piezoelectric sheets 41 to 44 as a whole are deforming into a convex shape protruding toward the pressure chamber 110 (i.e., a unimorph deformation). Here, the piezoelectric sheets 41 to 44 are fixed to the upper face of the cavity plate 122 which defines the pressure chambers 110. Therefore, a region of the piezoelectric sheets 41 to 44 corresponding to the active portion deforms into a convex shape protruding toward the pressure chamber 110. Such deformation reduces a volume of the pressure chamber 110 so that pressure, in other words, ejection energy is applied to ink contained in the pressure chamber 110. Thus, an ink droplet is ejected from the nozzle 108. Then, when the individual electrode 35 is returned to the same potential as that of the common electrode 34, the piezoelectric sheets 41 to 44 restore their original shape, and the pressure chamber 110 restores its original volume. Thus, ink is absorbed from the manifold channel 105 into the pressure chamber 110.

In another possible driving method, the individual electrode 35 is in advance kept at a potential different from the potential of the common electrode 34. Upon every ejection request, the individual electrode 35 is once set at the same potential as that of the common electrode 34 and then, at a predetermined timing, the individual electrode 35 is again set at the potential different from the potential of the common electrode 34. In this case, in an initial state, a region of the piezoelectric sheets 41 to 44 corresponding to the active portion deforms in a convex shape protruding toward the pressure chamber 110. When an ejection request is issued, at a timing when the individual electrode 35 and the common electrode 34 have the same potential, the piezoelectric sheets 41 to 44 restore their original flat shape, so that the volume of the pressure chamber 110 increases as compared with its initial state. As a result, ink is absorbed from the manifold channel 105 into the pressure chamber 110. Then, at a timing when the individual electrode 35 is again set at the potential different from the potential of the common electrode 34, the region of the piezoelectric sheets 41 to 44 corresponding to the active portion deforms into a convex shape protruding toward the pressure chamber 110, to reduce the volume of the pressure chamber 110 and thus raise pressure on ink which is thereby ejected.

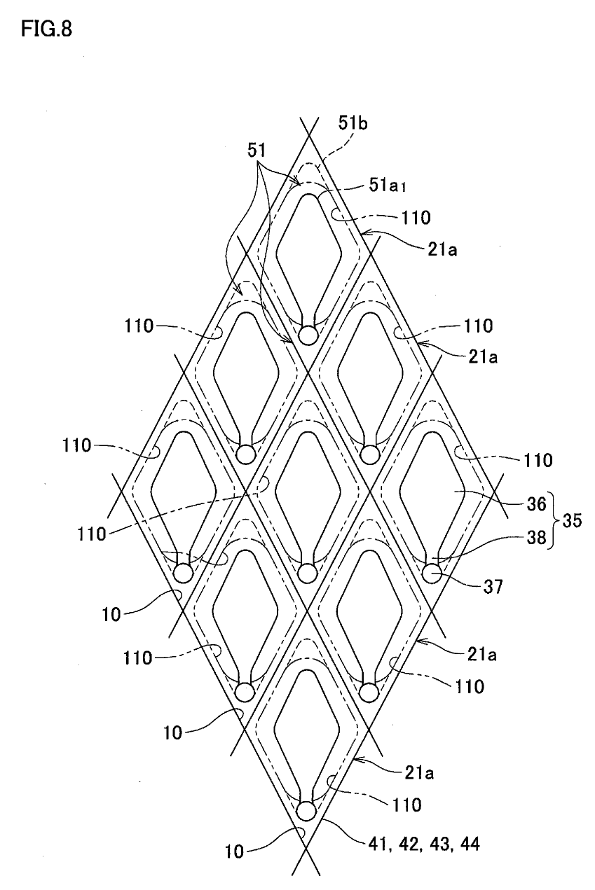

FIG. 8 is an explanatory view showing a part of actuators 21a and pressure chambers 110 arranged within one actuator group 21. A parallelogram region 10 is an imaginary region obtained by sectioning the upper face 9a of the passage unit 9 in a grid pattern. Pressure chambers 110 and actuators 21a corresponding to the respective pressure chambers 110 are arranged within each region 10. The piezoelectric sheets 41 to 44 included in the actuator 21a have, in a plan view, a parallelogram shape which is substantially the same as a shape defined by an outer edge of the region 10. The piezoelectric sheets 41 to 44 of neighboring actuators 21a are spaced at some distance from each other. In a plan view, the actuators 21a are arranged in a matrix so as to correspond to the pressure chambers 110. The land 37 is disposed at a position between main electrode portions 36 of two neighboring actuators 21a.

As described above, in the ink-jet head 1 of this embodiment, the land 37 is disposed above the overhang 51 as shown in FIG. 6. This enables the pressure chambers 110 to be arranged at a higher density as compared with when the land 37 is disposed out of a region opposed to the pressure chamber 110 (i.e., when the land 37 is disposed on a left side of the curved surface 51b in FIG. 6).

In a case where the piezoelectric sheets 41 to 44 extend over a plurality of pressure chambers 110, regions of the piezoelectric sheets 41 to 44 opposed to the individual electrodes 35 and the lands 37 deform upon application of voltage, to cause crosstalk between neighboring pressure chambers 110. In this embodiment, however, since the piezoelectric sheets 41 to 44 opposed to one pressure chamber 110 are spaced apart from the piezoelectric sheets 41 to 44 opposed to another pressure chamber 110, crosstalk hardly occurs. Therefore, even when nozzles 108 communicating with neighboring pressure chambers 110 simultaneously eject ink, a desired amount of ink is ejected from each nozzle 108 at a desired ink ejection speed. Thus, print quality is improved.

In addition, the land 37 overlaps the overhang 51 in a plan view. Accordingly, in bonding the terminal of the COF 50 to the land 37, in fixing the piezoelectric sheets 41 to 44 to the passage unit 9, or the like, pressure applied to the land 37 is transmitted to the overhang 51, which makes it difficult that the piezoelectric sheets 41 to 44 are damaged. If, for example, the land 37 is disposed at a position closer to the main electrode portion 36 and not overlapping the overhang 51 in order that the pressure chambers 110 can be arranged at a higher density, only four piezoelectric sheets 41 to 44 exist between the land 37 and the pressure chamber 110. In such a case, for preventing damage caused by pressure which is applied in bonding the terminal of the COF 50 to the land 37, in fixing the piezoelectric sheets 41 to 44 to the passage unit 9, or the like, reduced pressure must be applied, because the piezoelectric sheets 41 to 44 made of the ceramic material are fragile. As a result, strength of bonding between the land 37 and the terminal of the COF 50 or between the piezoelectric sheets 41 to 44 and the passage unit 9 cannot be high. In this embodiment, however, not only the piezoelectric sheets 41 to 44 but also the overhang 51 exists between the land 37 and the pressure chamber 110. Therefore, by a thickness of the overhang 51, rigidity increases and the piezoelectric sheets 41 to 44 become undamageable. As a result, the land 37 and the terminal of the COF 50, or the piezoelectric sheets 41 to 44 and the passage unit 9 can be firmly bonded to each other under sufficient pressure.

If, for example, a part of the land 37 does not overlap the overhang 51 but overlaps the pressure chamber 110, it is likely that a portion of the piezoelectric sheets 41 to 44 opposed to a region of the pressure chamber 110 not having the overhang 51 is damaged in bonding the terminal of the COF 50 to the land 37, in fixing the piezoelectric sheets 41 to 44 to the passage unit 9, or the like. In this embodiment, however, the land 37 has no part which does not overlap the overhang 51 but overlaps the pressure chamber 110 in a plan view, as shown in FIG. 7. Therefore, it is more difficult that the piezoelectric sheets 41 to 44 are damaged, and they can be firmly bonded to each other with sufficient force. In addition, since the land 37 does not overlap the pressure chamber 110 beyond the overhang 51, deformation of the piezoelectric sheets 41 to 44 is hardly hindered.

In this embodiment, moreover, the whole of the land 37 overlaps the overhang 51 in a plan view. This enables the pressure chambers 110 to be arranged at a further higher density as compared with when a part of the land 37 locates beyond the overhang 51 (on the left side of the curved surface 51b in FIG. 6).

Further, the whole of the pressure chamber 110 falls within the piezoelectric sheets 41 to 44 in a plan view, and the pressure chamber 110 has a parallelogram shape at one vertex of which the land 37 is provided. This enables the pressure chambers 110 to be efficiently arranged on the upper face 9a of the passage unit 9 so that the pressure chambers 110 are arranged at a further higher density.

The overhang 51 is formed at each of an ink inlet and an ink outlet of the pressure chamber 110, that is, each of acute portions of the pressure chamber 110 which communicate with the aperture 112 and the communication hole with the nozzle 108, respectively. As a result, ink can smoothly flow into and out of the pressure chamber 110, and therefore air bubbles hardly stay within the pressure chamber 110. Even if air bubbles are generated, they are easily discharged out of the pressure chamber 110. Air bubbles existing within the pressure chamber 110 may cause variation in ink ejection from each nozzle 108, which deteriorates print quality. In the above-described structure, such a problem can be relieved.

The side face 51a of the pressure chamber 110 corresponding to the overhang 51 has a curved shape as shown in FIG. 6. As a result, ink can smoothly flow into and out of the pressure chamber 110, and therefore air bubbles more hardly stay within the pressure chamber 110. Even if air bubbles are generated, they are more easily discharged out of the pressure chamber 110.

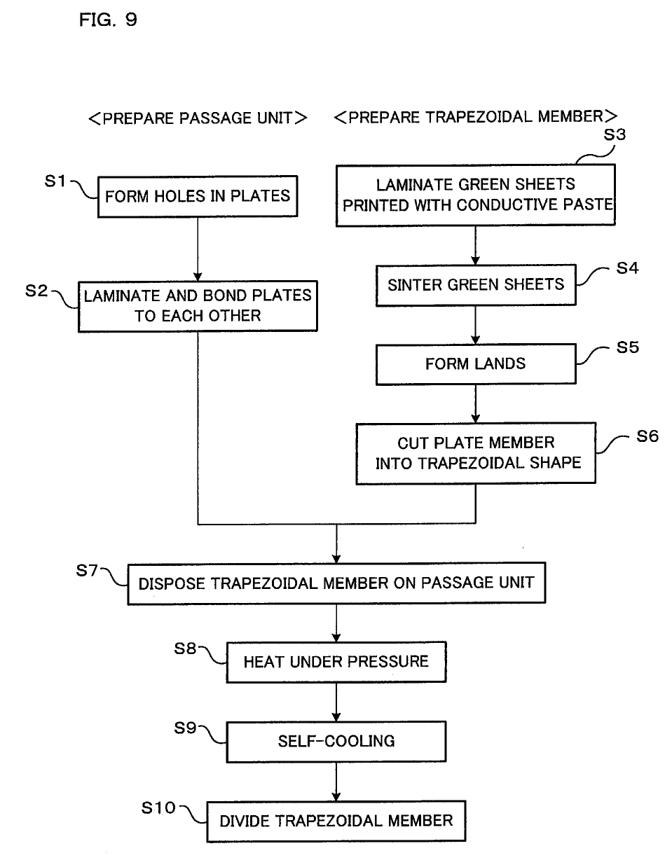

Next, a method of manufacturing the ink-jet head 1 of this embodiment will be described with reference to FIG. 9. FIG. 9 is a flowchart showing a method of manufacturing the head main body 2 which is included in the ink-jet head 1.

First, the passage unit 9 and a trapezoidal member which is a precursor of the actuator group 21 are prepared separately.

To prepare the passage unit 9, first, each of nine plates made of a metal such as stainless steel is subjected to etching with a mask of a patterned photoresist, so that holes are formed therein. Thus the plates 122 to 130 are prepared (S1). At this time, a plate which serves as the cavity plate 122 is etched in such a manner that an opening as a pressure chamber 110 is formed within each of a plurality of parallelogram regions 10 which are assumed in a face of this plate (see FIG. 8). More specifically, the side face 51a of the pressure chamber 110 is formed by performing the etching twice on one face with use of two masks, that is, a mask (resist film) having a relatively small hole corresponding to the inner edge 51a1 shown in FIG. 7, and a mask (resist film) having a relatively large hole corresponding to the outer edge of the curved surface 51b. By performing the etching in this way, the overhang 51 having the above-described shape can be easily formed at the side face 51a.

Then, the plates 122 to 130 are put in layers with interposition of an epoxy-base thermosetting adhesive, while being positioned to each other so as to form individual ink passages 132 shown in FIG. 5. Then, they are heated under pressure up to a temperature equal to or higher than a curing temperature of the thermosetting adhesive. As a result, the thermosetting adhesive is cured to secure the plates 122 to 130 to each other. Thus, the passage unit 9 can be obtained.

To prepare the trapezoidal member which is a precursor of the actuator group 21, first, four green sheets made of piezoelectric ceramic are prepared. The green sheets are prepared in consideration of an estimated amount of contraction which will be caused by sintering beforehand. On two of the green sheets, a conductive paste is screen-printed in a pattern of the individual electrodes 35 and the common electrode 34. Then, two unprinted green sheets are put while positioning the green sheets to each other using a jig. The green sheet printed with the pattern of the common electrode 34 is put thereon, with the printed side up. Further, the green sheet printed with the pattern of the individual electrodes 34 is put thereon, with the printed side up (S3).

A layered structure thus obtained in S3 is degreased like the known ceramics, and sintered at a predetermined temperature (S4). Consequently, the four green sheets turn into the piezoelectric sheets 41 to 44, and the conductive paste turns into the individual electrodes 35 and the common electrode 34. Then, gold including glass frits is printed on an extension 38 of each individual electrode 35, to form a plurality of lands 37 (S5). As a result, a plate member having a plurality of individual electrodes 35 and lands 37 formed on an uppermost face thereof and a common electrode 34 formed inside thereof is obtained. Then, the plate member is cut along a trapezoidal shape which corresponds to a region of the actuator group 21 (S6). In this way, four trapezoidal members which are precursors of the actuator groups 21 are obtained.

Then, the four trapezoidal members are disposed on the upper face 9a of the passage unit 9 with interposition of a thermosetting adhesive, at regions of the actuator groups 21 shown in FIG. 3, respectively (S7). At this time, the trapezoidal members are positioned to each other in such a manner that the individual electrodes 35 are opposed to the respective pressure chambers 110, that each land 37 is wholly accommodated within the parallelogram region 10, and that the land 37 overlaps the overhang 51.

Then, a heating and pressurizing device such as a ceramic heater is placed on the trapezoidal member so as to be supported by the lands 37, to apply pressure to the layered structure of the passage unit 9 and the trapezoidal members while heating it up to a temperature equal to or higher than a curing temperature of the thermosetting adhesive (S8). In S9, this layered structure is self-cooled and then, using a cutter, the trapezoidal member is sectioned into a plurality of parallelogram regions 10 shown in FIG. 8 (S10). Thus, the trapezoidal member is divided into a plurality of actuators 21a which are included in the actuator group 21. The actuators 21a thus formed, each of which is opposed to a pressure chamber 110 and closes an opening of the pressure chamber 110, are spaced apart from each other with respect to a plane direction.

Through the above-described steps, the head main body 2 is completed. Thereafter, a thermosetting conductive adhesive is applied onto the lands 37. The terminals formed on the COF 50 and the lands 37 are positioned so as to overlap each other, and in this state the COF 50 is heated and pressed toward the head main body 2, thereby bonding them to each other. Further, the reservoir unit 71 is fixed to the upper face 9a of the passage unit 9, and thus the ink-jet head 1 is completed.

As thus far described above, in the method of manufacturing the ink-jet head of this embodiment, since the land 37 is wholly accommodated within the parallelogram region 10 as shown in FIG. 8. Therefore, in S10, the trapezoidal member may be divided straight into a grid. If, for example, the land 37 is disposed across neighboring parallelogram regions 10, it is impossible to divide the trapezoidal member straight into a grid, and a process performed in S10 becomes difficult. In this embodiment, however, the trapezoidal member can be easily divided by the cutter.

Since the step of preparing the passage unit 9 and the step of preparing the trapezoidal member which is a precursor of the actuator group 21 are performed independently of each other, either one of them may precede the other, or alternatively they may be performed concurrently.

As a modification of the manufacturing method, it may be possible that, after the trapezoidal members are fixed onto the passage unit 9, the individual electrodes 35 and/or the land 37 are formed on the piezoelectric sheet 41. It may be also possible that the piezoelectric sheets 41 to 44 are sequentially put on the passage unit 9 and sintered. It may be possible to divide the trapezoidal member in advance before fixing it onto the passage unit 9, and to fix actuators 21a obtained by this division respectively onto the passage unit 9.

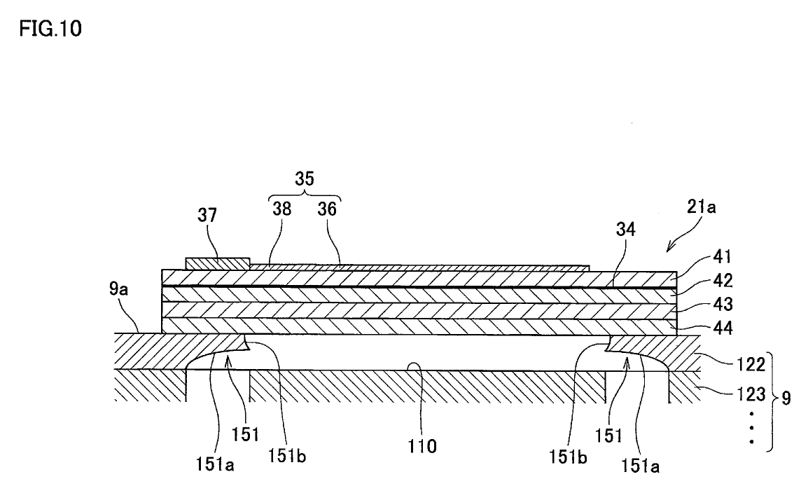

Next, modifications of the overhang will be described with reference to FIGS. 10, 11, and 12. The same members as described above will be denoted by the same reference numerals, without a specific description thereof.

In a modification shown in FIG. 10, an amount of protrusion of an overhang 151 is maximum at a position slightly below the upper face 9a of the passage unit 9, and the amount decreases at a position more downward away from the upper ace 9a. The pressure chamber 110 having overhangs 151 may be formed by etching a lower face of the cavity plate 122 so as to form a hole 151a extending over a communication hole which communicates with the sub manifold channel 105a and a communication hole which communicates with the nozzle 108, and in addition etching an upper face of the cavity plate 122 so as to form a hole 151b having a shape similar to but smaller than the hole 151a. By etching both sides of the cavity plate 122 like this, the pressure chambers 110 can be formed at accurate positions in the cavity plate 122. Therefore, an ink-jet head having pressure chambers 110 with a high positioning accuracy can be manufactured. This is because the two holes 151a and 151b which constitute the pressure chamber 110 can be formed while their positions are controlled from both sides of the cavity plate 122.

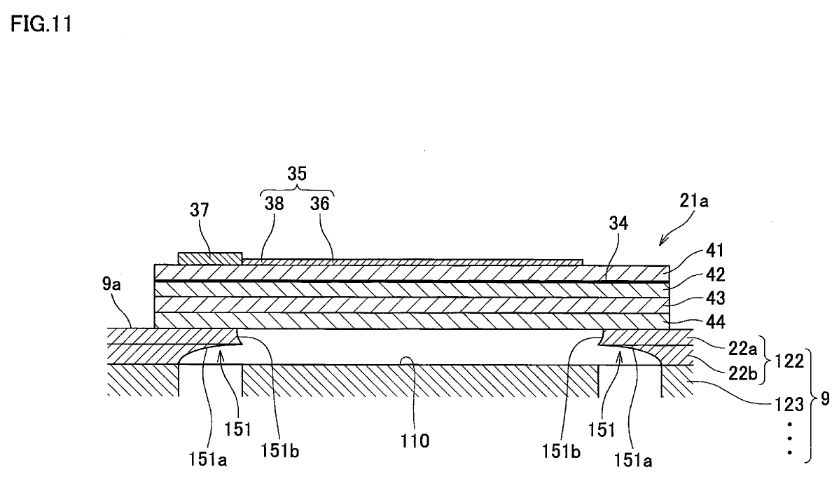

A modification shown in FIG. 11 is the same as the modification shown in FIG. 10, except that the cavity plate 122 includes two sheets 22a and 22b. Holes 151a and holes 151b are formed in the sheets 22a and 22b, respectively. The cavity plate 122 is formed by making the sheets 22a and 22b adhere to each other in such a manner that the holes 151a and 151b communicate each other to form a single hole. Like this, the cavity plate 122 includes two sheets 22a and 22b. This offers high degree of freedom in determining a shape of a side wall of the pressure chamber 110. Therefore, the side wall of the pressure chamber 110 can be easily formed into a shape different from the shape shown in FIG. 11.

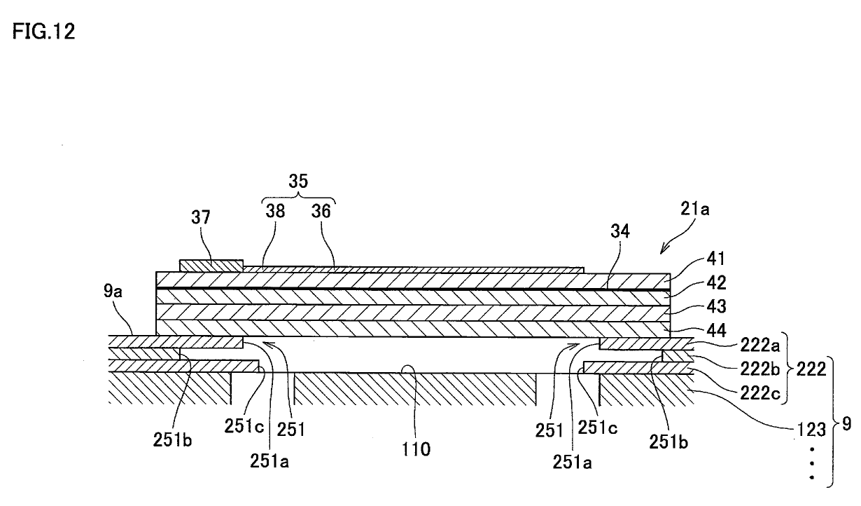

In a modification shown in FIG. 12, a cavity plate 222 includes three sheets 222a, 222b, and 222c. The sheets 222a to 222c, which have holes 251a, 251b, and 251c, respectively, are put in layers so as to make the holes 251a to 251c overlap each other. The holes 251a to 251c have substantially parallelogram shapes which are similar to each other. The hole 251a is smaller than the hole 251b and larger than the hole 251c. A portion of the uppermost sheet 22a protruding from the sheet 222b serves as an overhang 251. Although the sheet 222c also protrudes in the same direction as the sheet 222a does, pressure applied to the land 37 is transmitted to the protruding portion of the sheet 222a because there is a gap between the sheet 222a and the sheet 222c. Therefore, the sheet 222c does not contribute to increase in pressure for bonding to the terminal of the COF 50 or pressure for bonding the piezoelectric sheets 41 to 44 to the passage unit 9. As a modification similar to the modification shown in FIG. 12, it may be possible that a cavity plate includes three sheets among which the uppermost sheet has the largest hole while the lower sheets have holes of the same size or while lowermost one of the two sheets has a larger hole than the other of them has. In any case, a portion protruding toward inside of the pressure chamber receives pressure applied in laminating and fixing the actuator or the COF, to prevent the pressure from causing damage to the actuator.

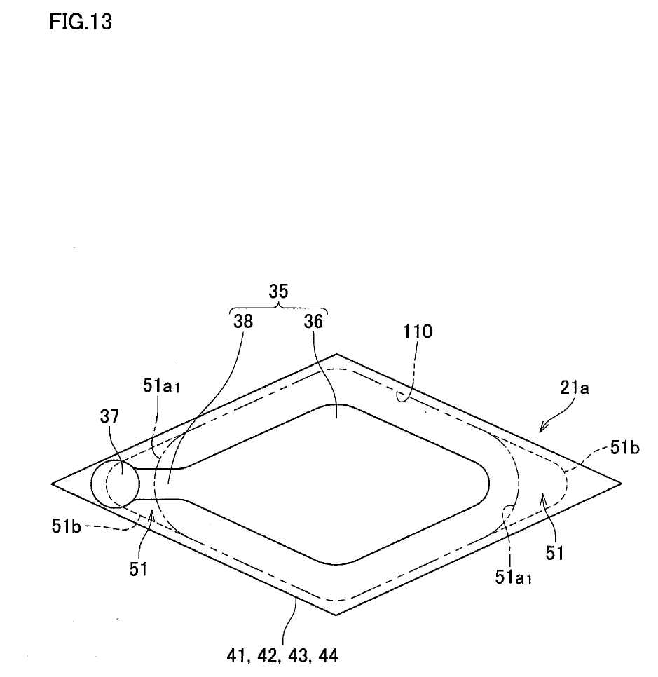

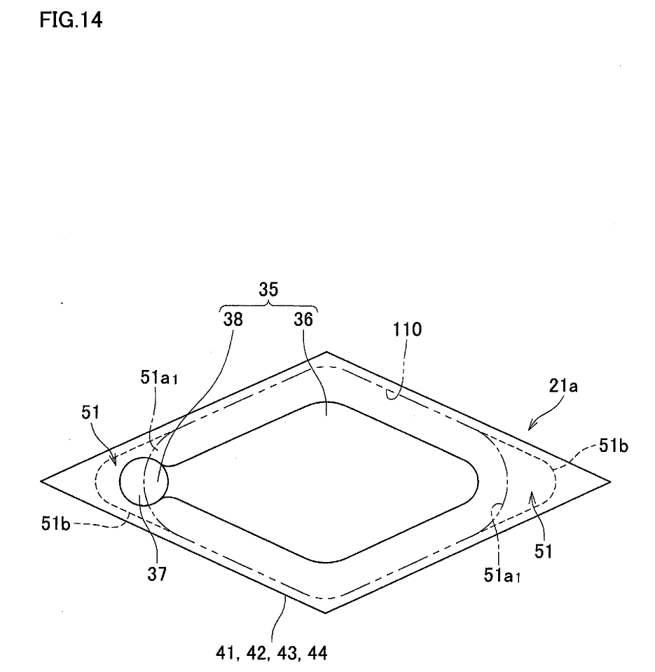

Next, modifications of a location of the land 37 will be described with reference to FIGS. 13 and 14. The same members as described above will be denoted by the same reference numerals, without a specific description thereof.

In modifications shown in FIGS. 13 and 14, the land 37 partially, not wholly, overlaps the overhang 51. The land 37 shown in FIG. 13 is disposed more away from the pressure chamber 110 than in the embodiment shown in FIG. 7. The land 37 shown in FIG. 14 is disposed closer to the pressure chamber 110 than in the embodiment shown in FIG. 7. The extension 38 shown in FIG. 13 is longer than the extension 38 shown in FIG. 7, and the extension 38 shown in FIG. 14 is shorter than the extension 38 shown in FIG. 7. Like this, it suffices that at least a part of the land 37 overlaps the overhang 51 in a plan view. In a structure shown in FIG. 14, a part of the land 37 is located on an opening of the pressure chamber 110. In order to prevent the actuator from being damaged in laminating and fixing the actuator and the COF, it is preferable that at least a center of the land 37 is at a position overlapping the overhang 51.

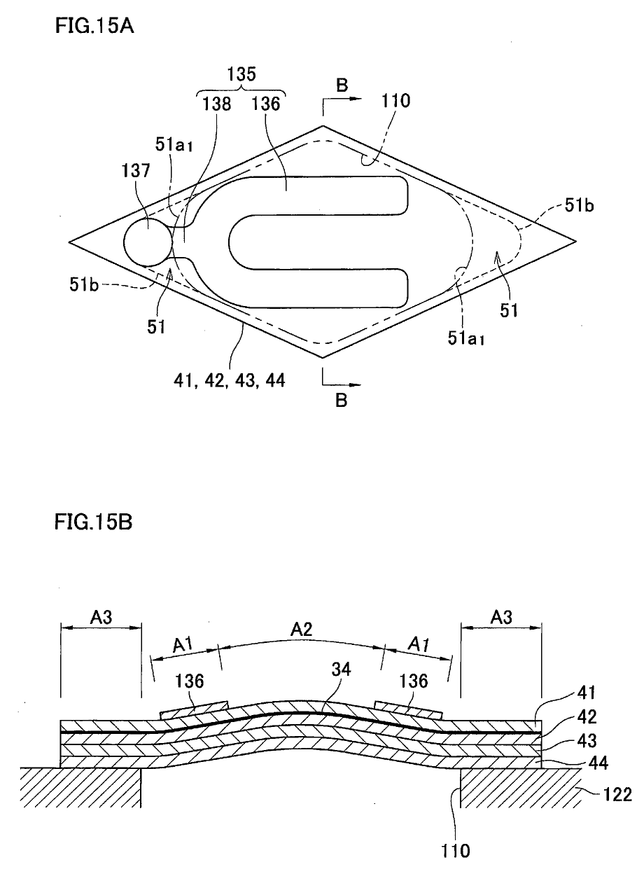

Next, a modification of the individual electrode will be described with reference to FIGS. 15A and 15B. The same members as described above will be denoted by the same reference numerals, without a specific description thereof.

In the modification shown in FIGS. 15A and 15B, an individual electrode 135 has a main electrode portion 136 and an extension 138. The main electrode portion 136 has a U-like shape extending in a lengthwise direction of the pressure chamber 110. The extension 138 extends out from a portion of the main electrode portion 136 corresponding to one acute portion of the pressure chamber 110. The main electrode portion 136 is disposed so as to avoid a center of the pressure chamber 110. A land 137 is formed on a surface of a distal end of the extension 138. Like in the above-described embodiment, a whole of the land 137 overlaps the overhang 51 in a plan view.

When drive voltage is supplied to the individual electrode 135, an active portion of the piezoelectric sheet 41 which is sandwiched between the main electrode portion 136 and the common electrode 34, that is, a portion corresponding to a region A1 shown in FIG. 15B, is applied with an electric field in a polarization direction which means a thickness direction. This makes the active portion of the piezoelectric sheet 41 contract in a direction perpendicular to the polarization direction, that is, in a plane direction, because of a transversal piezoelectric effect. On the other hand, since a portion of the piezoelectric sheets 42 to 44 corresponding to the region A1 does not deform by itself. Thus, a difference occurs between distortion in the plane direction of the upper piezoelectric sheet 41 and distortion in the plane direction of the lower piezoelectric sheets 42 to 44. As a result, the portion of the piezoelectric sheets 41 to 44 corresponding to the region A1 as a whole is deforming into a convex shape protruding toward the pressure chamber 110. Here, a portion of the piezoelectric sheets 41 to 44 corresponding to a region A3 is fixed to the upper face of the cavity plate 122. Therefore, the portion of the piezoelectric sheets 41 to 44 corresponding to the region A1 deforms so as to warp against the pressure chamber 110. Accordingly, a portion of the piezoelectric sheets 41 to 44 corresponding to a region A2, which does not deform by itself, also deforms so as to warp against the pressure chamber 110. As a result, as shown in FIG. 15B, a portion of the piezoelectric sheets 41 to 44 opposed to the pressure chamber 110 deforms protrudingly toward a side opposite to a pressure chamber 110 side. This increases a volume of the pressure chamber 110, to produce a negative pressure wave within the pressure chamber 110. By stopping voltage supply to the individual electrode 135 at a timing when the pressure wave propagates in one way along a length of the pressure chamber 110 and turns into a positive pressure wave, the piezoelectric sheets 41 to 44 restore their original flat state and the volume of the pressure chamber 110 decreases. At this time, the pressure wave generated while the volume of the pressure chamber 110 is increasing, and the pressure wave generated while the piezoelectric sheets 41 to 44 are restoring their original state are synthesized so that high pressure is applied to ink contained in the pressure chamber 110 to eject an ink droplet from the nozzle 108.

In the modification shown in FIGS. 15A and 15B, the volume of the pressure chamber 110 can be changed efficiently, and the actuator 21a can be driven by a relatively low drive voltage.

A shape of the overhang is not limited to the above-described one, as long as an interior space has such a shape that its length along the upper face 9a of the passage unit 9 increases at a portion more distant from the upper face 9a. The overhang may be provided at only one of the ink inlet and the ink outlet of the pressure chamber 110, or alternatively may be provided at a portion different from the inlet and the outlet.

In the above-described embodiment, the common electrode 34 and the piezoelectric sheets 42 to 44 function as a diaphragm, but other various diaphragms may be employed. For example, it may be possible to replace the piezoelectric sheets 43 and 44 with a flat plate made of a conductive material. In such a case, the common electrode 34 and the flat plate are not electrically connected, because the piezoelectric sheet 42 is an insulating material. Alternatively, it may also be possible that the common electrode 34 and the piezoelectric sheets 42 and 43 are omitted and at the same time the piezoelectric sheet 44 is replaced with a flat plate made of a conductive material which is used as a diaphragm serving as a common electrode. In such a case, the flat plate may be disposed over a plurality of pressure chambers 110. It may also be possible to omit the piezoelectric sheets 43 and 44 and make the piezoelectric sheet 42 extend over a plurality of pressure chambers 110. At this time, the common electrode 34 may be formed individually for every pressure chamber 110, or may be formed over a plurality of pressure chambers 110.

Materials of the piezoelectric sheet and the electrodes included in the actuator 21a are not limited to the above-described ones. Other known materials may be used. As the inactive layer, an insulating sheet other than the piezoelectric sheet may be used. The number of layers including the active portion, the number of inactive layers, and the like may be changed appropriately. The number of individual electrodes and common electrodes may be changed appropriately in accordance with the number of piezoelectric sheets. In the above-described embodiment, the common electrode 34 is kept at the ground potential. However, this is not limiting, as long as the potential of the common electrode 34 is common to the pressure chambers 110. Although in the above-described embodiment the inactive layer is disposed closer to the pressure chamber 110 than the layer including active portion is, the layer including the active portion may be disposed closer to the pressure chamber 110 than the inactive layer is, or alternatively the inactive layer may not be provided. However, by providing the inactive layer at a side closer to the pressure chamber 110 than the layer including the active portion is as in the above-described embodiment, it can be expected that the actuator 21a deforms with improved efficiency.

In the above-described embodiment, the actuator groups 21 including a plurality of actuators 21a are arranged in a zigzag pattern. However, the actuator groups 21 may be arranged in a single row, or in a zigzag pattern with three or more rows. It is not always necessary that the region of the actuator group 21 has a trapezoidal shape. Moreover, it is not always necessary that the actuators 21a form groups.

The pressure chambers 110 and the individual electrodes 35 corresponding to the respective pressure chambers 110 may not necessarily arranged in a matrix, but may be arranged in a single row.

It is not always necessary that the pressure chamber 110 and the individual electrode 35 have parallelogram shapes in a plan view. Various shapes may be acceptable. The region 10 which accommodates the pressure chamber 110 may not necessarily have a parallelogram shape, but may have various shapes.

The ink-jet head according to the present invention is not limited to a line printer, and may be applied to a serial printer with a reciprocating head. Further, applications of the ink-jet head according to the present invention are not limited to printers, and it is also applicable to ink-jet type facsimiles or copying machines, and the like.

While this invention has been described in conjunction with the specific embodiments outlined above, it is evident that many alternatives, modifications and variations will be apparent to those skilled in the art. Accordingly, the preferred embodiments of the invention as set forth above are intended to be illustrative, not limiting. Various changes may be made without departing from the spirit and scope of the invention as defined in the following claims.

What is claimed is:

1. A liquid ejection head comprising:
a passage member including a plurality of individual liquid passages each of which has a liquid ejection opening and a pressure chamber corresponding to the liquid ejection opening, and a plane on which a plurality of openings are formed to expose an interior space of each pressure chamber;
one or a plurality of diaphragms which are fixed to the plane so as to close the openings;
a plurality of piezoelectric layers which are spaced apart from each other with respect to a direction along the plane and formed on the diaphragms so as to be opposed to the respective pressure chambers;
a plurality of individual electrodes which are formed on the respective piezoelectric layers; and
a plurality of lands which are electrically connected to the respective individual electrodes and which have their height from a surface of the piezoelectric layers higher than that of the individual electrodes,
wherein:
an overhang is formed on a side wall of each pressure chamber in such a manner that a length of the interior space along the plane increases at a portion more distant from the plane; and
at least a part of each land overlaps the overhang of a pressure chamber corresponding to the land when seen in a direction perpendicular to the plane.

2. The liquid ejection head according to claim 1, wherein the land has no portion not overlapping the overhang but overlapping the pressure chamber, when seen in the direction perpendicular to the plane.

3. The liquid ejection head according to claim 2, wherein a whole of the land overlaps the overhang when seen in the direction perpendicular to the plane.

4. The liquid ejection head according to claim 1, wherein a whole of the pressure chamber is accommodated within a piezoelectric layer corresponding thereto when seen in the direction perpendicular to the plane.

5. The liquid ejection head according to claim 1, wherein the pressure chamber has a quadrangle shape at one vertex of which the land corresponding to the pressure chamber is provided, when seen in the direction perpendicular to the plane.

6. The liquid ejection head according to claim 1, wherein the overhang is formed at least one of a liquid inlet and a liquid outlet of the pressure chamber.

7. The liquid ejection head according to claim 6, wherein the overhang is provided at both of the liquid inlet and the liquid outlet of the pressure chamber.

8. The liquid ejection head according to claim 6, wherein the side wall of the pressure chamber corresponding to the overhang has a curved shape.

9. A method of manufacturing a liquid ejection head, comprising the steps of:
preparing a passage member including a plurality of individual liquid passages each of which has a liquid ejection opening and a pressure chamber corresponding to the liquid ejection opening, and a plane on which a plurality of openings are formed to expose an interior space of each pressure chamber;
fixing one or a plurality of diaphragms to the plane so as to close the openings;
placing a piezoelectric layer on the diaphragms so as to be opposed to the pressure chambers;
placing a plurality of individual electrodes on the piezoelectric layer so as to be opposed to the respective pressure chambers;
forming a plurality of lands which are electrically connected to the respective individual electrodes and which have their height from a surface of the piezoelectric layer higher than that of the individual electrodes; and
dividing the piezoelectric layer into a plurality of sections which are opposed to the respective pressure chambers and spaced apart from each other with respect to a direction along the plane,
wherein:
in the step of preparing the passage member, an overhang is formed on a side wall of each pressure chamber in such a manner that a length of the interior space along the plane increases at a portion more distant from the plane, and in addition each of the openings is positioned within each of a plurality of quadrangle regions by which the plane is sectioned into a grid; and
in the step of forming the lands, a whole of each land is made accommodated within the quadrangle region, and at least a part of each land is made overlap the overhang of a pressure chamber corresponding to the land when seen in a direction perpendicular to the plane.
